(19) United States
(12) Patent Application Publication
(10) Pub. No.: US 2014/0338714 A1
(43) Pub. Date: Nov. 20, 2014

(54) Thermoelectric Assembly And Device, In Particular For Generating An Electric Current In A Motor Vehicle

(71) Applicant: Valeo Systemes Thermiques, Le Mensil Saint Denis (FR)

(72) Inventors: Gerard Gille, Thorigne-en-Charnie (FR); Patrick Boisselle, Laval (FR); Veronique Monnet, Change (FR)

(21) Appl. No.: 14/008,608

(22) PCT Filed: Mar. 29, 2012
(86) PCT No.: PCT/EP2012/055743

§ 371 Date: Jun. 18, 2014

(30) Foreign Application Priority Data
Mar. 31, 2011 (FR) 1152699

(51) Int. Cl. H01L 35/30

(52) U.S. Cl. CPC H01L 35/30
USPC 136/205

(57) ABSTRACT

An assembly is formed of a plurality of tubes (1, 2) for circulating a fluid. The tubes (1, 2) extend parallel to one another. The assembly is further formed of a plurality of thermoelectric elements (3) making it possible to create an electric current from a temperature gradient applied between two contact surfaces (4a, 4b) thereof. The thermoelectric elements (3) are distributed over the tubes (1, 2) with which the thermoelectric elements (3) are in contact via one (4b) of their contact surfaces. The assembly is designed so as to enable the installation of tubes for circulating another fluid, with the tubes being intended to be in contact with the thermoelectric elements (3) via the other (4a) contact surface thereof and extending in a direction that is a secant relative to the direction of extension of the tubes (1, 2). A thermoelectric device is equipped with a stack of assemblies.

The present invention relates to an assembly formed of a plurality of tubes for circulating a fluid and of a plurality of elements referred to as thermoelectric elements making it possible to create an electric current from a temperature gradient. The invention also relates to a thermoelectric device, in particular for generating an electric current in a motor vehicle, comprising such assemblies.

Thermoelectric devices using elements referred to as thermoelectric elements making it possible to generate an electric current in the presence of a temperature gradient between two opposed surfaces thereof in accordance with the phenomenon known as the Seebeck effect have already been proposed. These devices comprise a stack of first tubes for circulating the exhaust gases of an engine and a stack of second tubes for circulating a coolant in a cooling circuit. The thermoelectric elements are sandwiched between the tubes so as to be subjected to a temperature gradient originating from the difference in temperature between the hot exhaust gases and the cold coolant.

Such devices are particularly advantageous because they make it possible to produce electricity from a conversion of the heat originating from the exhaust gases of the engine. They thus provide the possibility of reducing the fuel consumption of the vehicle by acting as a substitute, at least in part, for the alternator usually provided in said vehicle for generating electricity from a belt driven by the crankshaft of the engine.

A disadvantage encountered with the known devices is that they require very good contact between the thermoelectric elements and the tubes in order to ensure satisfactory conduction therebetween. It is thus necessary to provide tubes that are perfectly flat and have an excellent surface condition, thus impacting the cost price of the device.

The greater the electric power to be provided, the greater must be the number of tubes to be stacked and/or the larger must be the surface of the tubes to be used, again complicating effective application of the thermoelectric elements over the tubes.

A first solution, consisting in reinforcing the contact by means of external straps exerting a compressive force onto the stack of tubes, has been tested. This solution however requires the use of tubes that are not at risk of being crushed against one another under the effect of this force, thus resulting in an overconsumption of material. In addition, the quality of the contact ensured remains insufficient, in particular due to the disparity in size of the thermoelectric elements.

The object of the invention is to improve the situation by proposing an assembly formed of a plurality of tubes for circulating a fluid, said tubes extending parallel to one another, and of a plurality of elements referred to as thermoelectric elements making it possible to create an electric current from a temperature gradient applied between two surfaces thereof referred to as contact surfaces, said thermoelectric elements being distributed over said plurality of tubes with which the thermoelectric elements are in contact via one of their contact surfaces, said assembly being designed so as to enable the installation of tubes for circulating another fluid, said tubes being intended to be in contact with said thermoelectric elements via the other contact surface thereof and extending in a direction that is a secant relative to the direction of extension of the fluid circulation tubes of said assembly.

By subdividing the circulation path of one and/or the other of the fluids into a plurality of tubes, the contact surfaces with the thermoelectric elements are segmented and the consideration of the differences in size of said thermoelectric elements is facilitated. The exertion of a compressive force of the thermoelectric elements on the tubes can also be better distributed.

In accordance with different embodiments of the invention, considered together or separately:
said thermoelectric elements are distributed in groups distanced from one another in said direction of extension of the circulation tubes of said assembly,
said direction of extension of said tubes for circulating the other fluid is a direction orthogonal to the direction of extension of the circulation tubes of said assembly,
said circulation tubes of said assembly are distanced from one another in a direction orthogonal to their direction of extension,
said circulation tubes of said assembly are flat,
said circulation tubes of said assembly have a plurality of fluid circulation channels,
the circulation tubes of said assembly are equipped with tracks for the conduction of the current generated by said thermoelectric elements,
said assembly further comprises a collector plate connecting one end of said circulation tubes of said assembly, in particular for the assembly comprising a plurality of tubes for allowing the circulation of fluid of higher temperature,
said assembly further comprises a collector tank in fluid communication with one end of said circulation tubes of said assembly, in particular for the assembly comprising a plurality of tubes for allowing the circulation of the fluid of lower temperature,
said circulation tubes of said assembly are able to allow a circulation of exhaust gases and the number of circulation tubes of said assembly is between three and five,
said circulation tubes of said assembly are able to allow a circulation of cooling liquid and the number of tubes of said assembly is between five and ten.

The invention also relates to a thermoelectric device comprising one or more assemblies formed of a plurality of tubes for circulating a first fluid, referred to as a hot fluid, and of a plurality of thermoelectric elements as described above, alternating in a direction, referred to as the stacking direction, with assemblies formed of a plurality of tubes for circulating a second fluid, referred to as a cold fluid, having a temperature lower than that of the hot fluid, and of a plurality of thermoelectric elements, also as described above, the direction of extension of the tubes for circulating the cold fluid being a secant, in particular orthogonal, relative to the direction of extension of the tubes for circulating the hot fluid, so as to define zones of intersection between the tubes, said thermoelectric elements being provided at said zones and said thermoelectric elements of one of said assemblies being in contact with the tubes of a neighboring assembly.

In accordance with an aspect of the invention, the tubes of said assemblies have two opposed surfaces and the thermoelectric elements of one assembly of said assemblies are in contact with one of the surfaces of the tubes of said assembly, the thermoelectric elements of a neighboring assembly being in contact with the other surface of said tubes.

In accordance with another aspect of the invention, the device comprises means for compressing some of the tubes in the direction of other tubes in said stacking direction.

In accordance with an embodiment, the compression means comprise tightening rods oriented in the stacking direction.

The tubes for circulating the first fluid and the tubes for circulating the second fluid are designed, for example, to allow passages for said tightening rods between said zones of intersection.

In accordance with this aspect of the invention, compression is ensured at multiple points, and moreover as close as possible to the thermoelectric elements. Tightening points are thus distributed over the entire surface of the device. Uniform tightening forces could thus be weaker and more homogeneous, enabling improved contact between the tubes and the thermoelectric elements as a whole.

In accordance with a further aspect of the invention, the tubes for circulating the cold fluid are connected in a serpentine pattern from one assembly comprising said tubes for circulating cold fluid to a neighboring assembly comprising said tubes for circulating cold fluid.

In accordance with a further aspect of the invention, the device comprises a collector tank in fluid communication with the tubes for circulating the hot fluid, said tank being arranged at one end of said tubes.

The invention will be better understood in light of the following description, which is given merely by way of example and is in no way intended to limit the invention, accompanied by the annexed drawings, in which:

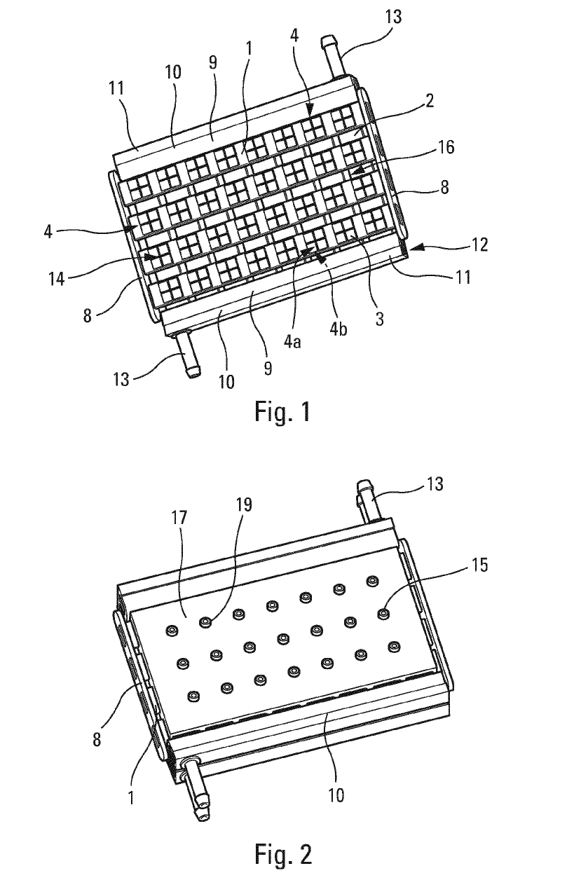

FIG. 1 illustrates a perspective view of two exemplary embodiments of an assembly according to the invention, stacked one above the other,

FIG. 2 illustrates a perspective view of a first exemplary embodiment of a device according to the invention,

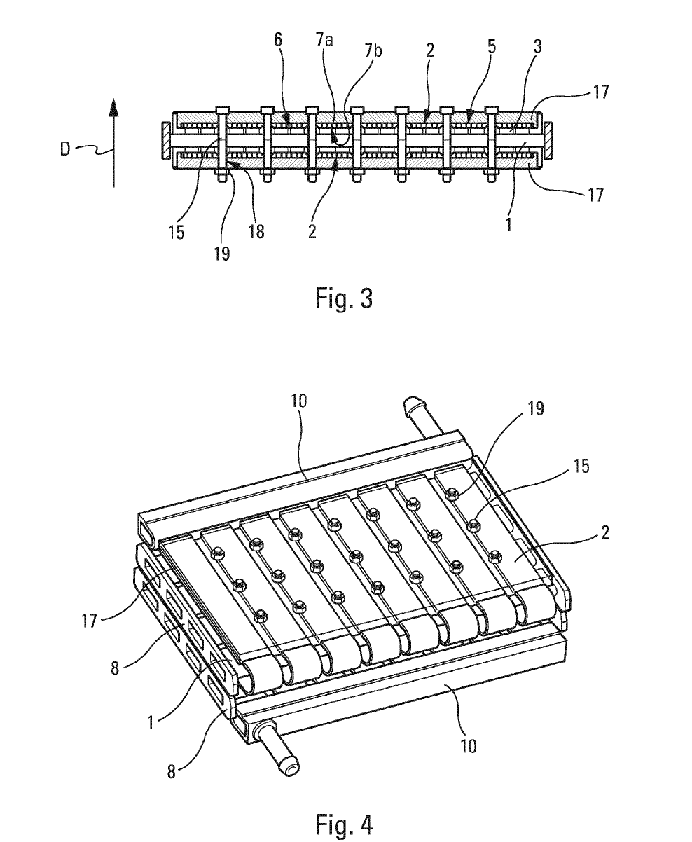

FIG. 3 is a view along a sectional plane orthogonal to the direction of extension of the tubes for circulating the cold fluid of the device of FIG. 2,

FIG. 4 illustrates a perspective view of a further exemplary embodiment of a device according to the invention.

As illustrated in FIG. 1, the invention firstly relates to an assembly formed of a plurality of tubes 1, 2 for circulating a fluid, extending parallel to one another. A plurality of tubes 1 for circulating a fluid referred to as a hot fluid and a plurality of tubes 2 for circulating a fluid referred to as a cold fluid and having a temperature lower than the temperature of the hot fluid are shown in this figure and belong, respectively, to a stacked first and second assembly according to the invention.

In the example, the circulation tubes 1 of the first assembly are intended to allow the circulation of exhaust gases and are between three and five in number, in this case four, whereas the circulation tubes 2 of the second assembly are intended to allow the circulation of a coolant and are between five and ten in number, in this case eight.

Said assemblies also comprise a plurality of elements 3, referred to as thermoelectric elements, making it possible to create an electric current from a temperature gradient applied between two of their surfaces 4a, 4b, referred to as contact surfaces (in FIG. 1, only the thermoelectric elements of the assembly equipped with the plurality of circulation tubes 1 is visible).

For example, these elements are elements having a substantially parallelepipedic shape generating an electric current by the Seebeck effect. Such elements allow the creation of an electric current in a charge connected between said contact surfaces 4a, 4b. In a manner known to a person skilled in the art, such elements are formed for example from bismuth and tellurium (Bi₂Te₃).

The thermoelectric elements could be, for a first part, elements 3p of a first type, referred to as the P type, making it possible to establish an electric potential difference in one direction, referred to as a positive direction, when they are subjected to a given temperature gradient, and, for the other part, could be elements 3n of a second type, referred to as the N type, making it possible to create an electric potential difference in an opposite direction, referred to as a negative direction, when they are subjected to the same temperature gradient.

Said thermoelectric elements 3 are distributed over said plurality of tubes 1 with which they are in contact via one of their contact surfaces 4b.

Said assembly is designed so as to enable the installation of tubes for circulating another fluid, said tubes being intended to be in contact with said thermoelectric elements 3 via the other 4a contact surface thereof and extending in a direction of extension that is a secant, in particular orthogonal, relative to the direction of extension of the fluid circulation tubes of said assembly. In FIG. 1, said tubes for circulating the other fluid are not shown, but could be designed identically to the circulation tubes 2 of the second assembly so as to be stacked in the same way on the circulation tubes 1 of the first assembly.

It is thus possible to establish a temperature gradient between the thermoelectric elements 3 in contact on the one hand with the circulation tubes 1 of the first assembly and also with tubes for circulating the other fluid.

The subdivision, within a same assembly, of the circulation of the fluids into a plurality of tubes makes it possible to have tubes which have a surface condition that is more satisfactory than in the case of larger tubes. In accordance with an exemplary embodiment of the invention, it also makes it possible, as described below, to exert a compressive force on the tubes that is as close as possible to the zones that have to be compressed in order to ensure effective contact with the thermoelectric elements 3.

The tubes 1, 2, are equipped for example with tracks (not illustrated) for the conduction of the current generated by said thermoelectric elements. More specifically, they could be covered with a layer of electrically insulating and thermally conductive material 35, for example ceramic, on which said tracks are provided, in particular made of copper. Said tracks connect in series and/or in parallel the thermoelectric elements 3 arranged on the tubes. All or some of the elements of the same type P or N of a tube 1, 2 could be regrouped so as to be assembled in parallel, whereas an element or a group of elements of type P of a tube will be assembled in series with an element or a group of elements of type N of the same tube or of another tube. In other words, different configurations of electric circuits could be provided on the surface of the tubes 1, 2.

Said thermoelectric elements 3 are distributed for example in groups 4, which are distanced from one another in the direction of extension of the circulation tubes 1, 2 of said assembly. The term “distanced” means that the distance between two neighboring thermoelectric elements within the same group 4 is much shorter than the distance between two neighboring groups 4. The thermoelectric elements are regrouped in fours in this case.

Said circulation tubes 1, 2 for example have a section that is flat in a longitudinal direction orthogonal to the direction of extension of the tubes. Said tubes 1, 2 within the same assembly are distanced from one another in said longitudinal direction, the advantage of which will be described further below.

Said circulation tubes 1, 2 are flat tubes for example. This means that they have two large parallel surfaces connected by short sides. Said pluralities of tubes 1, 2 also extend in planes parallel to said large surfaces.

As illustrated in FIG. 3, said tubes for example have a multiplicity of channels 5.

For the assemblies for circulating the cold fluid, said tubes 2 are formed for example of aluminum and/or aluminum alloy. They are extruded in particular. Their channels could be round in section.

For the assemblies for circulating the hot fluid, said tubes 2 are made in particular of stainless steel. They are formed for example by profiling, welding and/or brazing. The channels 5 for passage of the fluid are separated in particular by partitions 6 connecting the opposed planar surfaces 7a, 7b of the tubes.

If reference is made again to FIG. 1, it can be seen that said assembly could also comprise a collector plate 8, 9 connecting one end of said circulation tubes 1, 2 of said assembly. Said collector plate 8, 9 is provided for example at each end of the tubes within the same assembly.

The assembly or assemblies could also comprise a collector tank 10 in fluid communication with one end of said circulation tubes of said assembly. Said collector tank 10 is provided for example at each end of the tubes within the same assembly.

For the assemblies for circulating the cold fluid, the collector tanks 10 comprise said collector plates 9, provided in semi-cylindrical shape, and a cover 11 of complementary shape, partitions 12 being arranged at each longitudinal end of the tanks 10. Fluid inlet/outlet manifolds 13, assembled on said collector tanks 10, could also be provided.

As illustrated in FIGS. 2 to 4, the invention also relates to a thermoelectric device comprising one or more assemblies formed of a plurality of tubes 1 for circulating hot fluid and of a plurality of thermoelectric elements 3 as described above, said assembly/assemblies alternating in a direction D, referred to as the stacking direction, with assemblies formed of a plurality of tubes 2 for circulating the cold fluid and of a plurality of thermoelectric elements 3, also as described above.

The direction of extension of the tubes 2 for circulating the cold fluid is a secant, in particular orthogonal, relative to the direction of extension of the tubes 1 for circulating the hot fluid, so as to define zones of intersection 14 (visible most clearly in FIG. 1) between the tubes, said thermoelectric elements 3 being provided at said zones of intersection. In other words, a crossed flow of the hot and cold fluids is ensured and temperature gradient zones 14 are formed, distributed discretely.

The term intersection does not mean that the hot and cold tubes cut across one another, since, due to their superimposed arrangement, they are located in different planes, but rather that they overlap one another. In other words, it is their projections more specifically that cut across one another in the stacking direction.

Said thermoelectric elements 3 of one of said assemblies are in contact with the tubes of a neighboring assembly.

The assemblies comprising the tubes 2 for circulating the cold fluid could comprise the same number of tubes. The same is true for the assemblies comprising the tubes 1 for circulating hot fluid.

The stacking direction is also orthogonal to the direction of extension of the tubes 1 for circulating hot fluid and of the tubes 2 for circulating the cold fluid.

The tubes 2 in the first and last assemblies in the stacking direction may have thermoelectric elements 3 on only one of their surfaces.

The thermoelectric elements 3 in one assembly of said assemblies are in contact with one 7a of the surfaces of the tubes in said assembly, the thermoelectric elements 3 in a neighboring assembly being in contact with the other surface 7b of said tubes.

Electric connectors (not illustrated) connected to the electric circuits of said assemblies are provided for a connection of the device to an electric network which it will help to feed.

To facilitate a uniform compression of the tubes 1, 2, the tubes 1 for circulating the hot fluid and the tubes 2 for circulating the cold fluid are designed to allow a passage 16 between said zones of intersection 14.

The device could also comprise means for compressing some of the tubes in the direction of other tubes in said stacking direction.

Said compression means comprise tightening rods 15 oriented in the stacking direction and passing through said passages 16. Said compression means further comprise, for example, plates 17 equipped with holes 18 allowing the passage of the tightening rods 15, and nuts 19 making it possible to apply the plates 17 against the tubes of the first and the last assembly in the stacking direction by being tightened on said tightening rods 15.

A tightening distributed over each of the groups of thermo elements, which again makes it possible to improve the contact between the thermoelectric elements and the tubes for improved electrical conduction, is thus enabled.

Said device can also comprise a collector tank (not shown) in fluid communication with the tubes 1 for circulating the hot fluid, said tank being arranged at one of the ends of said tubes. For example a collector tank common to the tubes 1 for circulating hot fluid is provided at each of the ends of said tubes.

In this regard, for the assemblies for circulating the hot fluid, said collector plate 8 is planar for example and enables the fixation of a cover (not shown) defining, together with the plate 8, the collector tank or collector tanks. This tank or these tanks is/are equipped with hot fluid inlet/outlet orifices.

In accordance with the specific embodiment of FIG. 4, the tubes 2 for circulating the cold fluid are identical and are stacked one above the other, in the stacking direction, from one assembly comprising said tubes 2 for circulating cold fluid to another. Moreover, said tubes 2 for circulating cold fluid stacked one above the other are connected in a serpentine pattern. In other words, the device comprises serpentine tubes arranged at a distance from one another in the longitudinal direction of the section of the tubes.

The collector tanks 10 for the cold fluid will thus be arranged at the end of the serpentine tubes, in other words at the first and last pluralities of tubes 2 for circulating the cold fluid, in the stacking direction.

1. An assembly formed of a plurality of circulation tubes for circulating a fluid, said circulation tubes extending parallel to one another, and formed of a plurality of thermoelectric elements making it possible to create an electric current from a temperature gradient applied between two contact surfaces, said thermoelectric elements being distributed over said circulation tubes with which said thermoelectric elements are in contact via one of their contact surfaces, said assembly being designed so as to enable the installation of tubes for circulating another fluid, said tubes being intended to be in contact with said thermoelectric elements via the other contact surface thereof and extending in a direction that is a secant relative to the direction of extension of said circulation tubes of said assembly.

2. The assembly as claimed in claim 1, wherein said thermoelectric elements are distributed in groups distanced from one another in the direction of extension of said circulation tubes of said assembly.

3. The assembly as claimed in claim 1, wherein the direction of extension of said tubes for circulating the other fluid is a direction orthogonal to the direction of extension of said circulation tubes of said assembly.

4. The assembly as claimed in claim 1, wherein said circulation tubes are distanced from one another in a direction orthogonal to their direction of extension.

5. The assembly as claimed in claim 1, wherein said circulation tubes of said assembly are flat.

6. The assembly as claimed in claim 1, further comprising a collector plate connecting one end of said circulation tubes of said assembly.

7. The assembly as claimed in claim 1, further comprising a collector tank in fluid communication with one end of said circulation tubes of said assembly.

8. The assembly as claimed in claim 1, wherein said circulation tubes of said assembly are able to allow a circulation of exhaust gases, and wherein the number of circulation tubes of said assembly is between three and five.

9. The assembly as claimed in claim 1, wherein said circulation tubes of said assembly are able to allow a circulation of cooling liquid, and wherein the number of circulation tubes of said assembly is between five and ten.

10. A thermoelectric device, comprising one or more assemblies formed of a plurality of circulation tubes for circulating a first/hot fluid, and of a plurality of thermoelectric elements as claimed in claim 1, alternating in a stacking direction, with assemblies formed of a plurality of circulation tubes for circulating a second/cold fluid having a temperature lower than that of the hot fluid, and of a plurality of thermoelectric elements as also claimed in claim 1, the direction of extension of said circulation tubes for circulating the cold fluid being a secant relative to the direction of extension of said circulation tubes for circulating the hot fluid, so as to define zones of intersection between said circulation tubes, said thermoelectric elements being provided at said zones of intersection and said thermoelectric elements of one of said assemblies being in contact with said circulation tubes of a neighboring assembly.

11. The device as claimed in claim 10, wherein said circulation tubes of said assemblies have two opposed surfaces and said thermoelectric elements of one assembly of said assemblies are in contact with one of the surfaces of said circulation tubes of said one assembly, said thermoelectric elements of a neighboring assembly being in contact with the other surface of said circulation tubes.

12. The device as claimed in claim 11, further comprising means for compressing some of said circulation tubes in the direction of other circulation tubes in the stacking direction.

13. The device as claimed in claim 12, wherein said compression means comprise tightening rods oriented in the stacking direction, and wherein said circulation tubes for circulating the first fluid and said circulation tubes for circulating the second fluid are designed to allow passages for said tightening rods between said zones of intersection.

14. The device as claimed in claim 10, wherein said circulation tubes for circulating cold fluid are connected in a serpentine pattern from one assembly comprising said circulation tubes for circulating cold fluid to a neighboring assembly comprising said circulation tubes for circulating cold fluid.

15. The device as claimed in claim 10, further comprising a collector tank in fluid communication with said circulation tubes for circulating the hot fluid, said collector tank being arranged at one end of said circulation tubes.

16. The assembly as claimed in claim 2, wherein the direction of extension of said tubes for circulating the other fluid is a direction orthogonal to the direction of extension of said circulation tubes of said assembly.

17. The device as claimed in claim 13, wherein said circulation tubes for circulating cold fluid are connected in a serpentine pattern from one assembly comprising said circulation tubes for circulating cold fluid to a neighboring assembly comprising said circulation tubes for circulating cold fluid.

18. The device as claimed in claim 17, further comprising a collector tank in fluid communication with said circulation tubes for circulating the hot fluid, said collector tank being arranged at one end of said circulation tubes.
